(19) United States
(12) Patent Application Publication
(10) Pub. No.: US 2012/0178189 A1
(43) Pub. Date: Jul. 12, 2012

(54) METHOD FOR FORMING AN OVER PAD METALIZATION (OPM) ON A BOND PAD

(76) Inventor: Douglas M. Reber, Austin, TX (US)

(21) Appl. No.: 12/985,906

(22) Filed: Jan. 6, 2011

(51) Int. Cl. H01L 21/60; H01L 21/66

(52) U.S. Cl. 438/17; 438/612; 257/E21.506; 257/E21.531

(57) ABSTRACT

A method of making a semiconductor structure includes forming a bond pad, depositing by laser defined deposition a conductive pad, and attaching an electrical connector to the conductive pad. The bond pad is a portion of an integrated circuit. The bond pad includes an exposed portion. The bond pad functions as a contact to the integrated circuit. The conductive pad is deposited on the exposed portion and is confined within a bond pad region around the exposed portion of the bond pad

### BACKGROUND

1. Field

This disclosure relates generally to semiconductor processing, and more specifically, to forming an over pad metallization (OPM) on a bond pad.

2. Related Art

In current semiconductor packaging technologies, bond pads are typically used for both attaching wire bonds and performing probe tests. However, a bond pad which has been probed typically results in an unreliable subsequent wire bond connection, due to the damage to the bond pad caused by the probing. Therefore, in order to address this issue, bond pads are typically formed having a probe region adjacent a wirebond region, as shown in FIG. 1. That is, the probe region and wire bond region of the bond pad of FIG. 1 are not overlapping such that a wire bond will not be formed over a probed region of the bond pad. However, in order to accommodate both regions, bond pad sizes are elongated to provide for separation between the bond and probe regions. This results in larger bond pads, which becomes increasingly problematic as semiconductor devices continue to shrink in size.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a bond pad having a probe region and a wire bond region in accordance with the prior art.

FIG. 2 illustrates a cross-sectional view of a semiconductor structure at a stage in processing, in accordance with one embodiment of the present invention.

FIG. 3 illustrates a cross-sectional view of the semiconductor structure of FIG. 2 at a subsequent stage in processing, in accordance with one embodiment of the present invention.

FIG. 4 illustrates a cross-sectional view of the semiconductor structure of FIG. 3 at a subsequent stage in processing, in accordance with one embodiment of the present invention.

FIG. 5 illustrates a cross-sectional view of the semiconductor structure of FIG. 4 at a subsequent stage in processing, in accordance with one embodiment of the present invention.

FIG. 6 illustrates a cross-sectional view of the semiconductor structure of FIG. 5 at a subsequent stage in processing, in accordance with one embodiment of the present invention.

FIG. 7 illustrates a cross-sectional view of the semiconductor structure of FIG. 6 at a subsequent stage in processing, in accordance with one embodiment of the present invention.

FIG. 8 illustrates a cross-sectional view of the semiconductor structure of FIG. 7 at a subsequent stage in processing, in accordance with one embodiment of the present invention.

FIG. 9 illustrates a cross-sectional view of the semiconductor structure of FIG. 8 at a subsequent stage in processing, in accordance with one embodiment of the present invention.

FIG. 10 illustrates a cross-sectional view of the semiconductor structure of FIG. 9 at a subsequent stage in processing, in accordance with one embodiment of the present invention.

FIG. 11 illustrates a cross-sectional view of a semiconductor structure at a stage in processing, in accordance with one embodiment of the present invention.

FIG. 12 illustrates a cross-sectional view of the semiconductor structure of FIG. 11 at a subsequent stage in processing, in accordance with one embodiment of the present invention.

FIG. 13 illustrates a cross-sectional view of the semiconductor structure of FIG. 12 at a subsequent stage in processing, in accordance with one embodiment of the present invention.

FIG. 14 illustrates a top-down view of a bond pad in accordance with one embodiment of the present invention.

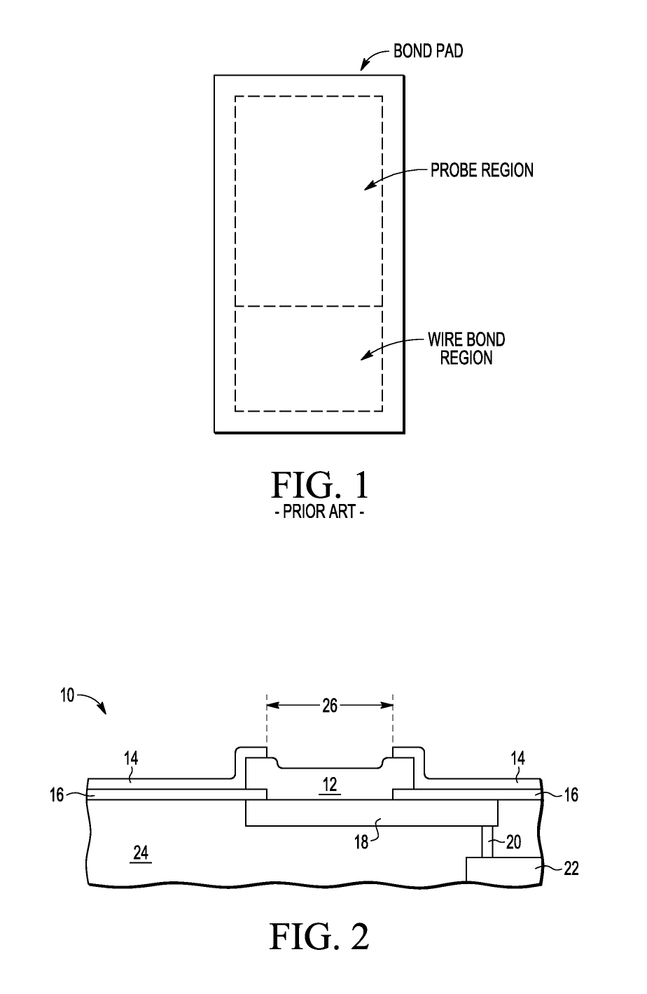

### DETAILED DESCRIPTION

In one embodiment, a conductive pad (e.g. an over pad metallization (OPM)) is selectively formed over a bond pad through the use of laser defined deposition in which a laser is used to define specific locations where a conductive layer is selectively formed. Laser defined deposition may include, for example, stereolithography or selective laser sintering. For example, stereolithography involves stereoscopic laser exposure of a suitably optically sensitive solution or bath, and selective laser sintering selectively fuses powdered material. In this manner, through the use of laser defined deposition, the conductive pad is selectively deposited on the bond pad. That is, the laser defined deposition allows for localized growth on the bond pads as defined by a laser. If probing is performed prior to formation of the conductive pad, the conductive pad seals up or reduces the damage caused by the die probe. Alternatively, probe testing can be performed after formation of the conductive pad but prior to formation of a wire bond, in which the conductive pad is able to sustain any damage caused by the probing and still result in a reliable wire bond. In this manner, the conductive pad allows for the wire bond region of a bond pad to be overlapping with the probe region. That is, a wire bond can subsequently be formed directly over a probe region which was previously probed.

FIG. 2 illustrates a cross-sectional view of a semiconductor structure 10 in accordance with one embodiment of the present invention. Semiconductor structure 10 includes a portion of a completed integrated circuit having a top metal layer 18 at a top surface of the integrated circuit, a first passivation layer 16 over top metal layer 18 which exposes a portion of top metal layer 18, a bond pad 12 formed over the exposed portion of top metal layer 18, and a final passivation layer 14 over first passivation layer 16 which exposes a portion 26 of bond pad 12. Note that passivation layers 14 and 16 may also be referred to as dielectrics. In the illustrated embodiment, final passivation layer 14 may include a nitride and may overlap a perimeter of bond pad 12. Therefore, in the illustrated embodiment, exposed portion 26 is smaller than bond pad 12. However, in alternate embodiments, note that final passivation layer 14 may not cover portions of bond pad 12. The integrated circuit of semiconductor structure 10 also includes a conductive via 20 and a next to last metal layer 22, in which conductive via 20 connects next to last metal layer 22 to top metal layer 18. Metal layers 18 and 22 are surrounded by a dielectric 24. Bond pad 12 may be connected to the integrated circuit of semiconductor structure 10 by way of a plurality of metal layers, including, for example, top metal layer 18, conductive via 20, and next to last metal layer 22.

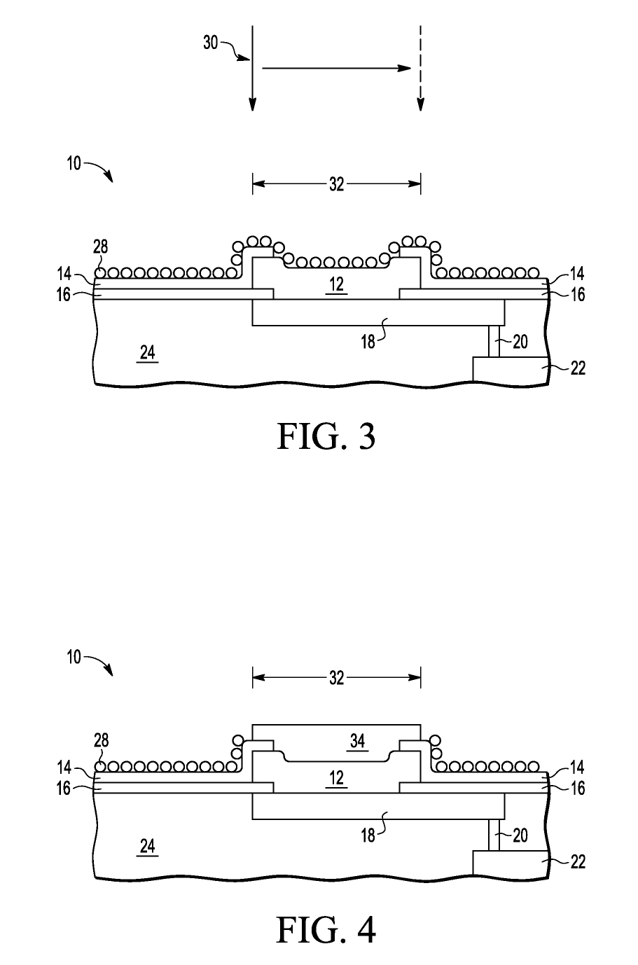

FIG. 3 illustrates a cross-sectional view of semiconductor structure 10 after a first portion of a laser defined deposition. In the illustrated embodiment, selective laser sintering is used to perform the laser defined deposition. In FIG. 3, a layer of powdered metallic material 28 is formed over final passivation layer 14 and bond pad 12. Subsequent to the formation of powdered metallic material 28, a laser beam 30 is directed to the powdered metallic material 28 located over bond pad 12. That is, laser beam 30 is directed to the locations of powdered material 28 where a conductive layer is desired. Therefore, in the illustrated embodiment, laser beam 30 is scanned across scan region 32 which is located directly over bond pad 12, encompassing all or most of the area of bond pad 12. Laser beam 30 results in the fusion of the powdered metallic material, resulting in a conductive layer 34 on bond pad 12 within scan region 32, as illustrated in FIG. 4. Furthermore, conductive layer 34 also attaches to the underlying layers, such as portions of final passivation layer 14 and exposed portion 26 of bond pad 12. Note that for those regions to which laser beam 30 was not directed, powdered metallic material 28 remains un-fused and unattached to underlying passivation layer 14. This process of applying a layer of powdered metallic material and directing a laser beam to particular scan regions is iteratively performed until a desired thickness of conductive layer 34 is achieved.

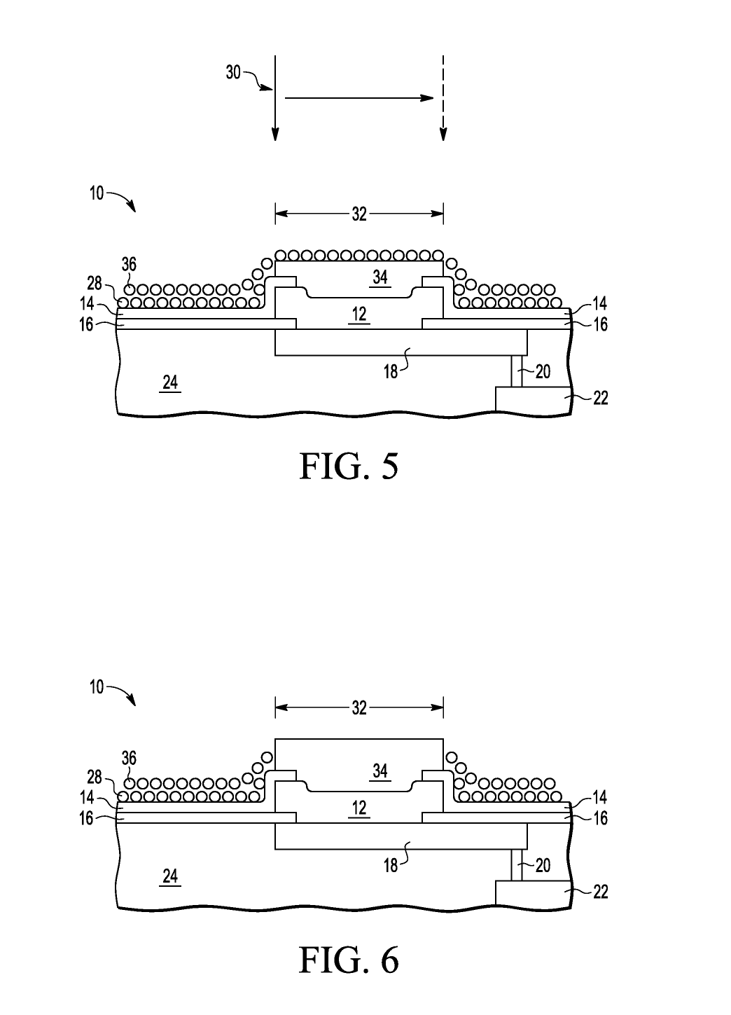

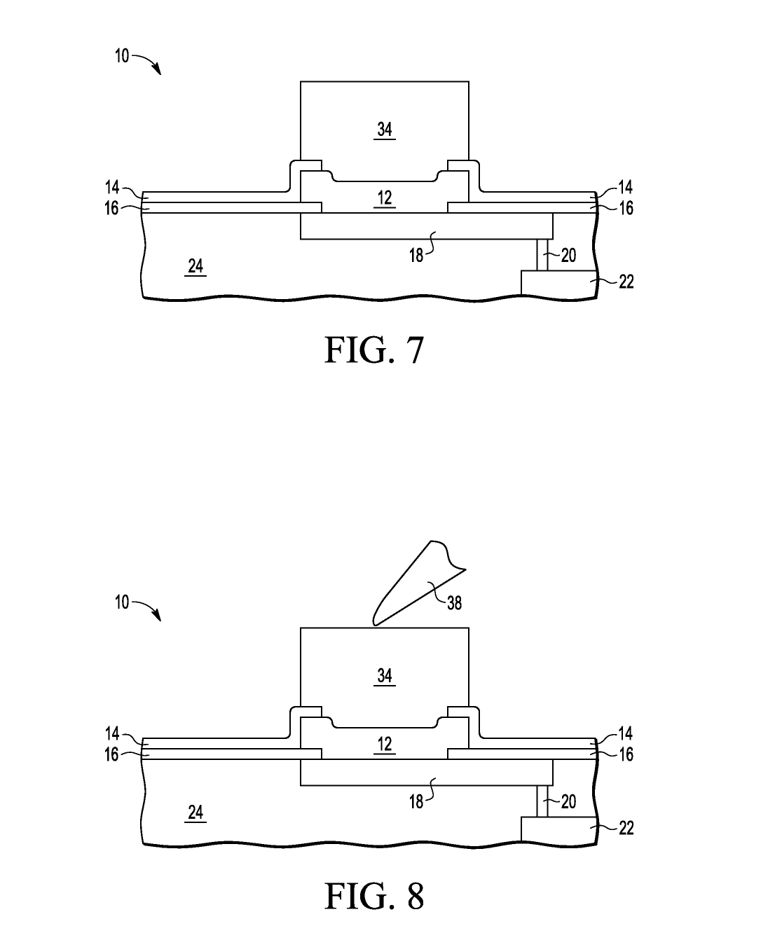

FIG. 5 illustrates semiconductor structure 10 after a subsequent iteration of the laser defined deposition (e.g. the selective laser sintering) started in FIG. 3. A layer of powdered metallic material 36 is formed over powdered metallic material 28 and over conductive layer 34. Laser beam 30 is again directed to the powdered metallic material 36 located over bond pad 12, within scan region 32. In this manner, as illustrated in FIG. 6, conductive layer 34 increases in thickness as the metallic particles over conductive layer 34 fuse and attach to the underlying previously formed portion of conductive layer 34. This process, as illustrated in FIGS. 5 and 6, is iteratively performed until conductive layer 34 reaches a desired thickness, as illustrated in FIG. 7.

Therefore, FIG. 7 illustrates semiconductor structure 10 after completion of formation of conductive layer 34 (also referred to as conductive pad 34) over bond pad 12 through the use of selective laser sintering. Alternatively, stereolithography may be used to form conductive layer 34 in which semiconductor structure 10 is placed in a bath and a laser beam is directed to those locations over the bond pads, as described above with respect to laser beam 30, in which the laser cures the liquid of the bath into a solid form which results in a metal or metal alloy bonded to the underlying layer. This process may also be iteratively repeated, where semiconductor structure 10 is lowered deeper into the bath each time, to achieve the desired thickness of the resulting metal or metal alloy to form conductive layer 34.

Therefore, through the use of laser defined deposition, conductive layer 34 can be selectively formed over the bond pads of semiconductor structure 10 by directing a laser beam only to those locations where formation of a conductive layer is desired. Furthermore, in the illustrated embodiment, when viewed top-down, conductive layer 34 has a side with a maximum length, L1, and exposed portion 26 of bond pad 12 has a side with a maximum length, L2. In one embodiment, L2 is less than or equal to 1.5*L1. In one embodiment, when viewed top-down, conductive layer 34 completely surrounds and covers exposed portion 26 of bond pad 12. Also, in the illustrated embodiment, conductive layer 34 is formed over bond pad 12 and over portions of final passivation layer 14 which extend over a perimeter of bond pad 12. However, in alternate embodiments, conductive layer 34 may not extend over final passivation layer 14.

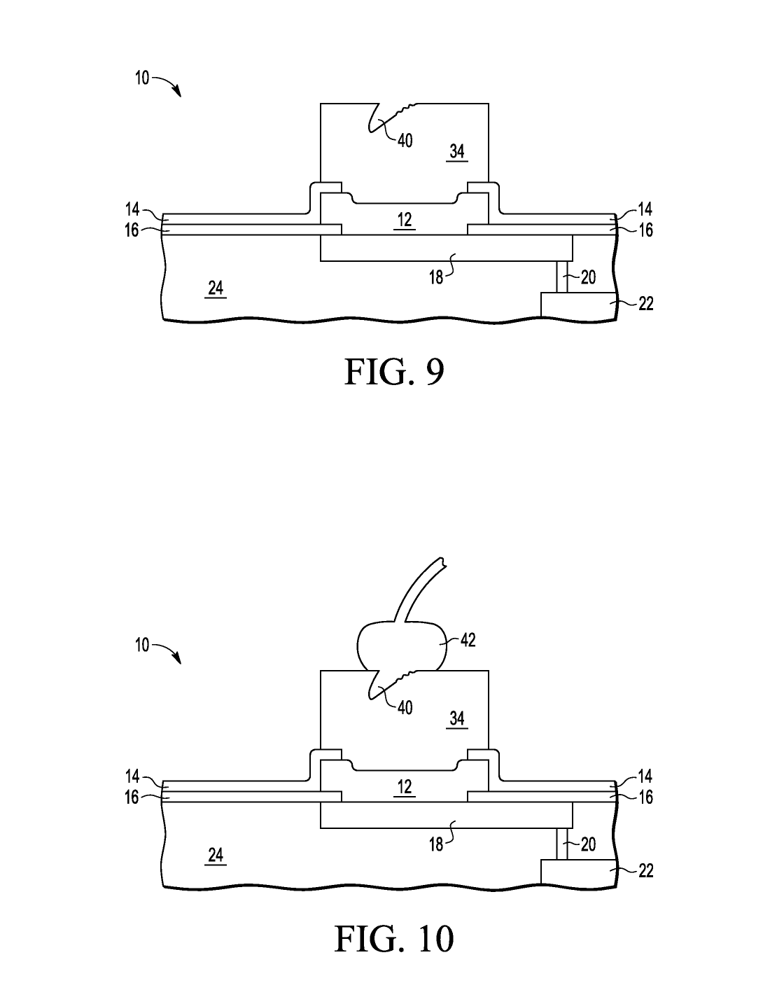

FIG. 8 illustrates semiconductor structure 10 during probe testing of the integrated circuit in which a probe tip 38 is applied to conductive layer 34 in order to electrically contact bond pad 12. FIG. 9 illustrates semiconductor structure 10 after probe testing in which conductive layer 34 includes an indentation 40 caused by probe damage. That is, since probe tips are typically driven into the conductive pads to which they are applied, indentations are formed, and the surface of the conductive pad may also be roughened do the rubbing of the probe tip on the pad.

FIG. 10 illustrates semiconductor structure 10 after formation of a wire bond 42 on conductive layer 34. Note that wire bond 42 may be formed over indent 40 and still provide a reliable connection. That is, the thickness and robustness of conductive layer 34 formed over bond pad 12 allows for a reliable wire bond formation. Furthermore, due to the presence of conductive layer 34, wire bond 42 may be formed directly over the damage caused by probing (e.g. directly over indentation 40). In this manner, as will be seen in FIG. 14 described below, the wire bond region of bond pad 12 may overlap, and may even completely overlap, probe region of bond pad 12, thus allowing for a reduced bond pad size for bond pad 12.

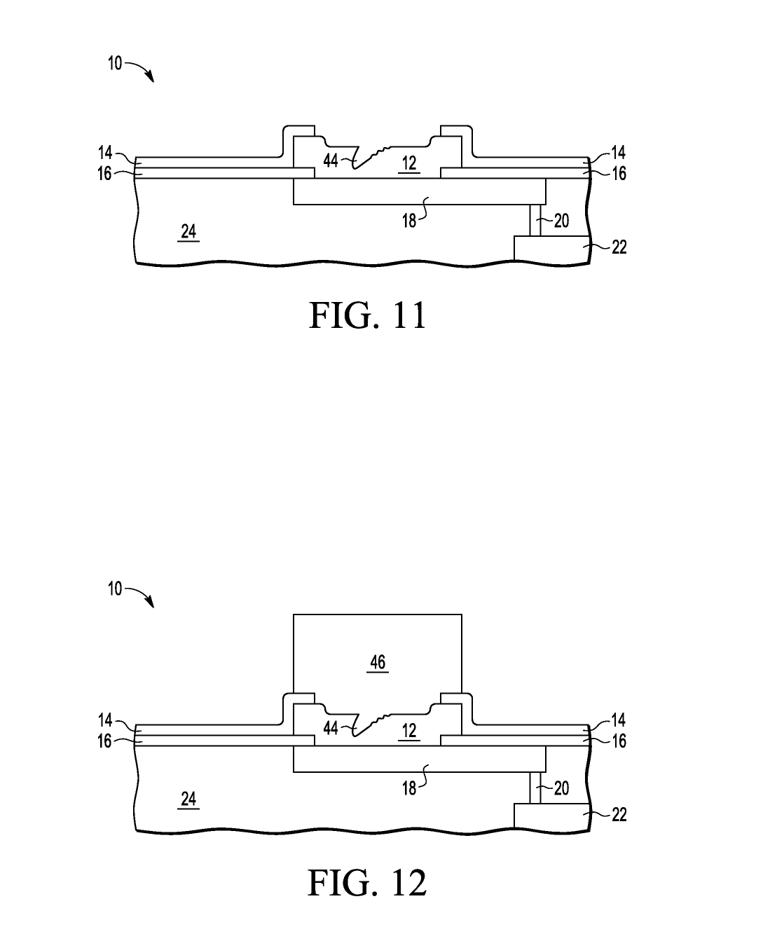

FIGS. 11-13 illustrate semiconductor structure 10 in which probing is performed prior to formation of a conductive layer or pad by laser defined deposition. FIG. 11 illustrates semiconductor structure 10, after formation of bond pad 12 and final passivation layer 14, which has been probed. Therefore, the probe testing of structure 10 using bond pad 12 results in indentation 44 which is caused by the probe tip damage (analogous to indentation 40 described above). That is, the probe tip has been directly applied to bond pad 12 to electrically contact bond pad 12 and to test the integrated circuit.

FIG. 12 illustrates semiconductor structure 10 after formation of conductive layer 46 (also referred to as conductive pad 46) by way of laser defined deposition. Formation of conductive layer 46 is analogous to formation of conductive layer 34 described above, therefore, all the descriptions for the formation of conductive layer 34 also apply to the formation of conductive layer 46. For example, any method of laser defined deposition, such as, for example, selective laser sintering or stereolithography, may be used to form conductive layer 46 in which a laser beam is directed to particular scan regions over semiconductor structure 10 where the formation of a conductive layer is desired. Also, in the illustrated embodiment, conductive layer 46 is formed over bond pad 12 and over portions of final passivation layer 14 which extend over a perimeter of bond pad 12. However, in alternate embodiments, conductive layer 46 may not extend over final passivation layer 14.

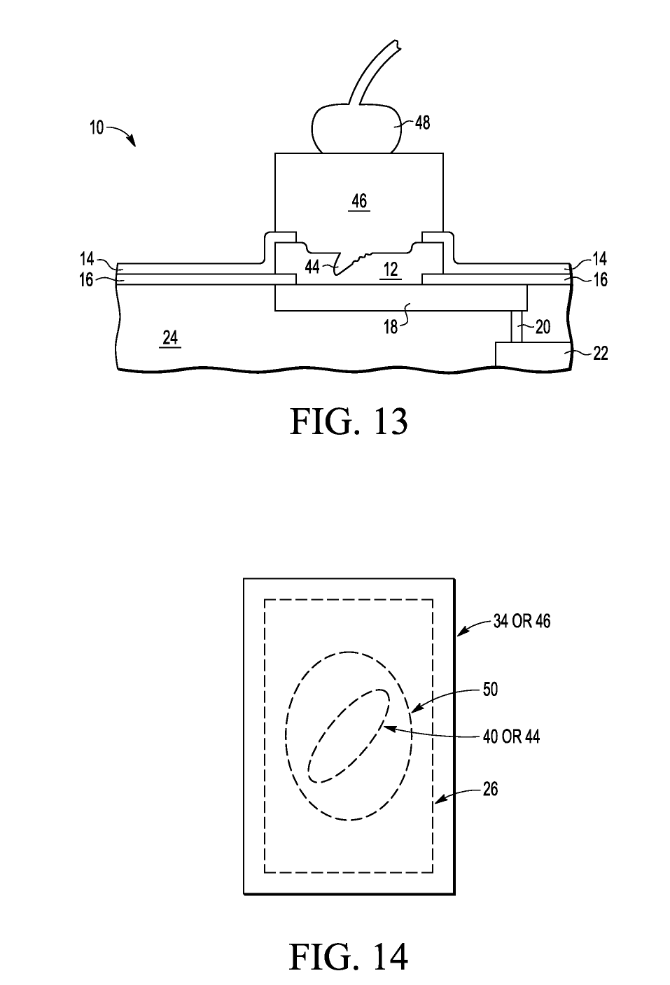

FIG. 13 illustrates semiconductor structure 10 after formation of a wire bond 48 over conductive layer 46. Therefore, typically the damage to bond pad 12 prevents the formation of a wire bond directly over the damaged portion of the bond pad. However, due to the presence of conductive layer 46, a wire bond can be formed directly over the damaged portion of the bond pad, which also allows for a reduced bond pad size for bond pad 12.

FIG. 14 illustrates a top-down view of conductive layer 34 or 46 (i.e. conductive pad 34 or 46, respectively), prior to the formation of a wire bond. In the illustrated embodiment, conductive layer 34 or 46 completely surrounds exposed portion 26 of bond pad 12. For example, conductive layer 34 or 46 is confined within a bond pad region around exposed portion 26 of bond pad 12. This bond pad region is the region intended to receive the wire bond (or other electrical connector such as a solder ball). Therefore, in one embodiment, the bond pad region of bond pad 12 may refer to a top surface of conductive layer 34 or 46, and may be larger in area than exposed portion 26 of bond pad 12. Also, as mentioned above, exposed portion 26 of bond pad 12 has a side with a maximum length, L1, and conductive layer 34 or 46 has a side with a maximum length, L2. In one embodiment, L2 is no more than 50 percent greater than L1. Also, within exposed portion 26 is indentation 40 or 44. Region 50 illustrates the region which will receive a wire bond (such as wire bond 42 or 48). That is, the dotted line labeled “40 or 44” may represent the probe region which overlaps the wire bond region. That is, the probe indentation (whether located directly on bond pad 12 or directly on conductive pad 34 or 46) can be located directly under wire bond region 50. In this manner, the wire bond region and the probe region of bond pad 12 may overlap and thus result in reduced pad size.

In FIGS. 10 and 13, a wire bond is attached to the bond pad region of conductive layer 34 and 46, respectively. However, in alternate embodiments, other types of electrical connectors, such as a solder ball, can be attached to conductive layer 34 or 46. Therefore, note that wire bond region, as used above, may also be referred to as a bonding region in which other types of connectors may be used. However, the presence of conductive layer 34 or 46 allows for a connector to be attached directly on or over the damage caused by probing.

By now it should be appreciated that there has been provided a method of forming a conductive pad on a bond pad through the use of laser defined deposition which may allow for reduced bond pad size. That is, the conductive pad allows for probe to be performed either before or after formation of the conductive pad, and allows for a wire bond or other electrical connection to be formed directly on or over the damage caused by probing.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, different implementations of laser defined deposition may be used. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention.

Item 1 includes a method of making a semiconductor structure including forming a bond pad as a portion of an integrated circuit, wherein the bond pad has an exposed portion and functions as a contact to the integrated circuit; depositing by laser defined deposition a conductive pad on the exposed portion and confined within a bond pad region around the exposed portion of the bond pad; and attaching an electrical connector to the conductive pad. Item 2 includes the method of item 1 and further includes probing the integrated circuit through the bond pad. Item 3 includes the method of item 2, wherein the probing comprises applying a probe directly to the exposed portion of the bond pad. Item 4 includes the method of item 3, wherein the step of probing causes an indentation in a top surface of the bond pad; and the step of attaching the electrical connector attaches the electrical connector directly over the indentation. Item 5 includes the method of item 2, wherein the probing comprises applying a probe directly to a top surface of the conductive pad prior to the step of attaching. Item 6 includes the method of item 5, wherein the step of probing causes an indentation in a top surface of the conductive pad; and the step of attaching the electrical connector attaches the electrical connector directly over the indentation. Item 7 includes the method of item 1, wherein the depositing includes applying powdered metallic material to cover the exposed portion of the bond pad; and directing a laser beam to the powdered metallic material over a scan region within the bond pad region. Item 8 includes the method of item 1, wherein the depositing comprises iteratively repeating a first step followed by a second step until the conductive pad is a predetermined thickness, and wherein the first step comprises applying a powdered metallic material over at least the exposed portion of the bond pad; and the second step comprises directing a laser beam to the metallic dust. Item 9 includes the method of item 1, wherein the forming the bond pad comprises forming a dielectric over a perimeter of the bond pad to define the exposed portion of the bond pad. Item 10 includes the method of item 1, wherein the forming the bond pad includes forming the bond pad directly on a portion of a top metal layer of the integrated circuit. Item 11 includes the method of item 9, wherein the depositing comprises forming the conductive pad to have a perimeter outside the perimeter of the bond pad. Item 12 includes the method of item 1, wherein the step of depositing comprises depositing the conductive pad on all of the exposed portion of the bond pad. Item 13 includes the method of item 1, wherein the step of attaching comprises attaching a wire bond as the connector. Item 14 includes the method of item 1, wherein the step of attaching comprises attaching a solder ball as the connector.

Item 15 includes a method of making a semiconductor structure, including forming a bond pad having an exposed surface and for providing an electrical contact of an integrated circuit; depositing a conductive pad on the exposed surface using laser defined deposition, wherein the exposed surface has a side with the maximum length and the conductive pad has a side with a maximum length no more than 50 percent greater than the side with the maximum length of the exposed surface; and attaching a connector over the conductive pad. Item 16 includes the method of item 15, wherein the step of depositing comprises performing a method using a laser beam selected from a group consisting of selective laser sintering and stereolithography. Item 17 includes the method of item 15, and further includes probing the integrated circuit using a probe applied over the exposed portion of the bond pad.

Item 18 includes a method of making a semiconductor structure, including forming a bond pad having an exposed surface, for providing an electrical contact of an integrated circuit, and for use in probing the integrated circuit; depositing a conductive pad on the exposed surface using laser defined deposition; probing the integrated circuit through the bond pad; and attaching a connector over the conductive pad. Item 19 includes the method of item 18, wherein the probing comprises applying a probe directly to the exposed portion of the bond pad and making an indentation in the exposed portion of the bond pad; and the attaching the connector comprises attaching the connector directly over the indentation. Item 20 includes the method of item 18, wherein the probing comprises applying a probe directly to the conductive pad and making an indentation in the conductive pad; and the attaching the connector comprises attaching the connector directly on the indentation.

What is claimed is:

1. A method of making a semiconductor structure, comprising:
forming a bond pad as a portion of an integrated circuit, wherein the bond pad has an exposed portion and functions as a contact to the integrated circuit;
depositing by laser defined deposition a conductive pad on the exposed portion and confined within a bond pad region around the exposed portion of the bond pad; and
attaching an electrical connector to the conductive pad.

2. The method of claim 1, further comprising probing the integrated circuit through the bond pad.

3. The method of claim 2, wherein the probing comprises applying a probe directly to the exposed portion of the bond pad.

4. The method of claim 3, wherein:
the step of probing causes an indentation in a top surface of the bond pad; and
the step of attaching the electrical connector attaches the electrical connector directly over the indentation.

5. The method of claim 2, wherein the probing comprises applying a probe directly to a top surface of the conductive pad prior to the step of attaching.

6. The method of claim 5, wherein:
the step of probing causes an indentation in a top surface of the conductive pad; and
the step of attaching the electrical connector attaches the electrical connector directly over the indentation.

7. The method of claim 1, wherein the depositing comprises:
applying powdered metallic material to cover the exposed portion of the bond pad; and
directing a laser beam to the powdered metallic material over a scan region within the bond pad region.

8. The method of claim 1, wherein the depositing comprises iteratively repeating a first step followed by a second step until the conductive pad is a predetermined thickness, wherein:
the first step comprises applying a powdered metallic material over at least the exposed portion of the bond pad; and
the second step comprises directing a laser beam to the metallic dust.

9. The method of claim 1, wherein the forming the bond pad comprises forming a dielectric over a perimeter of the bond pad to define the exposed portion of the bond pad.

10. The method of claim 1, wherein the forming the bond pad includes forming the bond pad directly on a portion of a top metal layer of the integrated circuit.

11. The method of claim 9, wherein the depositing comprises forming the conductive pad to have a perimeter outside the perimeter of the bond pad.

12. The method of claim 1, wherein the step of depositing comprises depositing the conductive pad on all of the exposed portion of the bond pad.

13. The method of claim 1, wherein the step of attaching comprises attaching a wire bond as the connector.

14. The method of claim 1, wherein the step of attaching comprises attaching a solder ball as the connector.

15. A method of making a semiconductor structure, comprising:
forming a bond pad having an exposed surface and for providing an electrical contact of an integrated circuit;
depositing a conductive pad on the exposed surface using laser defined deposition, wherein the exposed surface has a side with the maximum length and the conductive pad has a side with a maximum length no more than 50 percent greater than the side with the maximum length of the exposed surface; and
attaching a connector over the conductive pad.

16. The method of claim 15, wherein the step of depositing comprises performing a method using a laser beam selected from a group consisting of selective laser sintering and stereolithography.

17. The method of claim 15, further comprising probing the integrated circuit using a probe applied over the exposed portion of the bond pad.

18. A method of making a semiconductor structure, comprising:
forming a bond pad having an exposed surface, for providing an electrical contact of an integrated circuit, and for use in probing the integrated circuit;
depositing a conductive pad on the exposed surface using laser defined deposition;
probing the integrated circuit through the bond pad; and
attaching a connector over the conductive pad.

19. The method of claim 18, wherein:
the probing comprises applying a probe directly to the exposed portion of the bond pad and making an indentation in the exposed portion of the bond pad; and
the attaching the connector comprises attaching the connector directly over the indentation.

20. The method of claim 18, wherein:
the probing comprises applying a probe directly to the conductive pad and making an indentation in the conductive pad; and
the attaching the connector comprises attaching the connector directly on the indentation.
